(19) United States
(12) Patent Application Publication
(10) Pub. No.: US 2012/0048723 A1
(43) Pub. Date: Mar. 1, 2012

(54) SPUTTER TARGET FEED SYSTEM

(75) Inventor: Craig R. Chaney, Lanesville, MA (US)

(73) Assignee: VARIAN SEMICONDUCTOR EQUIPMENT ASSOCIATES, INC., Gloucester, MA (US)

(21) Appl. No.: 12/862,104

(22) Filed: Aug. 24, 2010

(51) Int. Cl. C23C 14/46; C23C 14/34

(52) U.S. Cl. 204/192.11; 204/298.23; 204/298.28; 204/192.12

(57) ABSTRACT

An apparatus includes an arc chamber housing defining an arc chamber, and a feed system configured to feed a sputter target into the arc chamber. A method includes feeding a sputter target into an arc chamber defined by an arc chamber housing, and ionizing a portion of the sputter target.

### FIELD

This disclosure relates generally to sputter targets, and more particularly to a feed system for a sputter target.

### BACKGROUND

A sputter target is a solid material which may be positioned within an arc chamber for sputtering of the sputter target. Sputtering is a process where energetic particles collide with the sputter target to dislodge particles of the sputter target from the same. A sputter target may be used in differing components and tools for differing purposes. One such component is an ion source used in a beam line ion implanter tool. Other tools that use a sputter target include, but are not limited to, deposition tools such as physical vapor deposition (PVD) or chemical vapor deposition (CVD) tools.

An ion source for a beam line ion implanter includes an arc chamber housing defining an arc chamber where the arc chamber housing also has an extraction aperture through which a well defined ion beam is extracted. The ion beam passes through the beam line of the beam line ion implanter and is delivered to a workpiece. The ion source is required to generate a stable, well-defined, uniform ion beam for a variety of different ion species. It is also desirable to operate the ion source in a production facility for extended periods of time without the need for maintenance or repair.

A conventional ion source having a sputter target places the sputter target of solid material completely in the arc chamber of the ion source. In operation, a sputter gas may be provided to the arc chamber. The sputter gas may be an inert gas such as argon (Ar), xenon (Xe), or krypton (Kr), or a reactive gas such as chlorine (Cl), BF₃, etc. The sputter gas may be ionized by electrons emitted from an electron source to form plasma in the arc chamber. The electrons may be provided by a filament, a cathode, or any other electron source. The plasma then sputter etches material from the sputter target, which in turn, is ionized by electrons in the plasma. Ions are then extracted through an extraction aperture into a well defined ion beam.

One drawback is the operational life time of the ion source or other tool is limited by the amount of sputter target material that can be placed completely in the arc chamber. The arc chamber has a finite size and the amount of sputter target material that can fit in the arc chamber is necessarily limited. Another drawback is that the sputter target is stationary and wear patterns tend to dictate when the sputter target needs to be replaced. As such, the stationary sputter target tends to be replaced before being fully consumed. Yet another drawback as it relates to ion sources for a beam line ion implanter is that a conventional sputter target ion source can not be operated in different non sputter operational modes thus limiting the operational modes and beam species.

Accordingly, it would be desirable to provide a feed system which overcomes the above-described inadequacies and shortcomings.

### SUMMARY

According to a first aspect of the disclosure an apparatus is provided. The apparatus includes an arc chamber housing defining an arc chamber, and a feed system configured to feed a sputter target into the arc chamber.

According to yet another aspect of the disclosure, a method is provided. The method includes feeding a sputter target into an arc chamber defined by an arc chamber housing, and etching a portion of the sputter target.

The present disclosure will now be described in more detail with reference to exemplary embodiments as shown in the accompanying drawings. While the present disclosure is described below with reference to exemplary embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

For a better understanding of the present disclosure, reference is made to the accompanying drawings, in which like elements are referenced with like numerals, and in which:

FIG. 1 is a simplified schematic block diagram of an ion implanter;

FIG. 2 is a diagram of an ion source consistent with an embodiment of the disclosure;

FIG. 3 is a plot of feed rate versus erosion rate;

FIG. 4 is a cross sectional end view of the ion source of FIG. 2 looking at the cathode of FIG. 2;

FIG. 5 is an end view of the rear wall of the ion source housing of FIG. 2;

FIG. 6 is a cross sectional plan view of another embodiment of an ion source consistent with an embodiment of the disclosure; and

FIG. 7 is an end view of the rear wall of FIG. 6 taken along the line 7-7 of FIG. 5.

### DETAILED DESCRIPTION

A feed system consistent with the present disclosure is detailed herein with respect to its use in an ion source of a beam line ion implanter 100. Those skilled in the art will recognize that the feed system may be beneficially implemented in any number of environments for any number of purposes including, but not limited to, deposition tools such as physical vapor deposition (PVD) or chemical vapor deposition (CVD) tools.

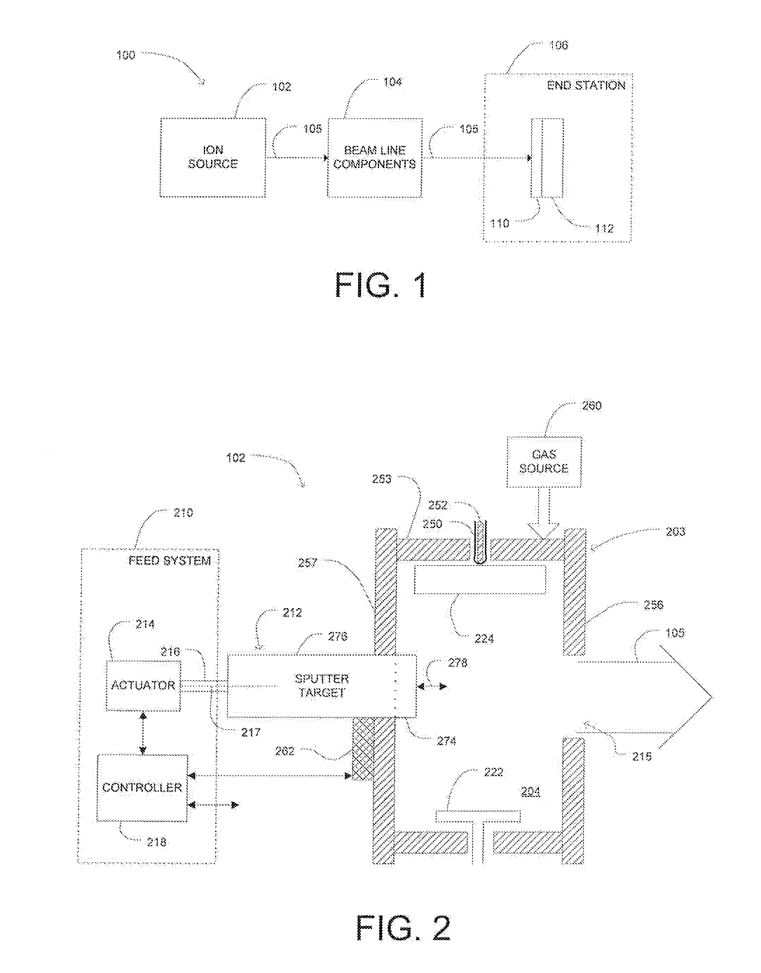

Turning to FIG. 1, a simplified schematic block diagram of an ion implanter 100 is illustrated. The ion implanter 100 includes an ion source 102 consistent with an embodiment of the disclosure, beam line components 104, and an end station 106 that supports one or more workpieces such as a workpiece 110. The ion source 102 generates an ion beam 105 that is directed via the beam line components 104 to the workpiece 110.

The beam line components 104 may include components known to those skilled in art to control and direct the ion beam 105 towards the workpiece 110. Some examples of such beam line components 104 include, but are not limited to, a mass analyzing magnet, a resolving aperture, ion beam acceleration and/or deceleration columns, an energy filter, and a collimator magnet or parallelizing lens. Those skilled in the art will recognize alternative and/or additional beam line components 104 that may be utilized in the ion implanter 100.

The end station 106 supports one or more workpieces, such as workpiece 110, in the path of ion beam 105 such that ions of the desired species strike the workpiece 110. The workpiece 110 may be, for example, a semiconductor wafer, a solar cell, a magnetic media, or another object receiving ion treatment for material modification. The end station 106 may include a platen 112 to support the workpiece 110. The platen 112 may secure the workpiece 110 using electrostatic forces. The end station 106 may also include a scanner (not illustrated) for moving the workpiece 110 in a desired direction.

The end station 106 may also include additional components known to those skilled in the art. For example, the end station 106 typically includes automated workpiece handling equipment for introducing workpieces into the ion implanter 100 and for removing workpieces after ion treatment. It will be understood to those skilled in the art that the entire path traversed by the ion beam is evacuated during ion treatment. The ion implanter 100 may also have a controller (not illustrated in FIG. 1) to control a variety of subsystems and components of the ion implanter 100.

Turning to FIG. 2, a schematic cross sectional view of an ion source 102 consistent with an embodiment of the disclosure is illustrated. For clarity of illustration, some components of the ion source 102 not necessary for an understanding of the disclosure are not illustrated. The ion source 102 includes an arc chamber housing 203 defining an arc chamber 204. The arc chamber housing 203 also includes a face plate 256, a rear wall 257 positioned opposite the face plate 256, and a sidewall 253. The face plate 256 further defines an extraction aperture 215 through which a well defined ion beam 105 is extracted.

The ion source 102 also include a feed system 210 configured to feed a sputter target 212 into the arc chamber 204. A cover 262 may be in an open position to expose an aperture in the rear wall 257 through which the sputter target 212 may be fed. The feed system 210 may include an actuator 214 to drive a shaft 216 coupled to the sputter target 212. The actuator 214 may include a motor, gear train, linkages, etc. to drive the shaft 216. The feed system 210 may also include a controller 218. The controller 218 can be or include a general-purpose computer or network of general-purpose computers that may be programmed to perform desired input/output functions. The controller 218 can also include other electronic circuitry or components, such as application specific integrated circuits, other hardwired or programmable electronic devices, discrete element circuits, etc. The controller 218 may provide a signal to the actuator 214 and receive signals from the same. The controller 218 may also send and receive signals from other components such as sensors and components, e.g., the cover 262, power supplies, beam current sensors, etc., to monitor the ion source and the ion implanter and control components of the same.

The sputter target 212 may be a variety of different solid materials depending on the desired dopant species. When boron (B) is the desired dopant species, the sputter target 212 may be a boron-containing solid material such as a boron alloy, a boride, and mixtures thereof. When phosphorous (P) is the desired dopant species, the sputter target 212 may be a phosphorous-containing solid material. The sputter target 212 may have a melting point between about 400° C. and 3,000° C. depending on the type of solid material. The vaporization point may also vary depending on the type of solid material.

The ion source 102 may also include a cathode 224 and a repeller 222 positioned within the arc chamber 204. The repeller 222 may be electrically isolated. A cathode insulator (not illustrated) may be positioned relative to the cathode 224 to electrically and thermally insulate the cathode 224 from the arc chamber housing 203. A filament 250 may be positioned outside the arc chamber 204 in close proximity to the cathode 224 to heat the cathode 224. A support rod 252 may support the cathode 224 and the filament 250. A gas source 260 may provide a gas to arc chamber 204 for ionization.

An extraction electrode assembly (not illustrated) is positioned proximate the extraction aperture 215 for extraction of the well-defined ion beam 105. One or more power supplies (not illustrated) may also be provided such as a filament power supply to provide current to the filament 250 for heating thereof and an arc power supply to the bias the arc chamber housing 203.

In operation, the ion source 102 may be operated in a first sputtering mode. In this mode, the cover 262 is moved to an open position to expose an aperture in the rear wall 257. The cover 262 may include a drive mechanism responsive to the controller 218 to move between an open and a closed position. The feed system 210 initially positions a portion 274 of the sputter target 212 in the arc chamber 204 with a remaining portion 276 positioned outside the arc chamber 204. The gas source 260 may provide a sputter gas to the arc chamber 204. The sputter gas may be an inert gas such as Ar, Xe, or Kr, etc. or a reactive gas such as Cl, BF₃, etc.

The filament 250 is heated by an associated power supply to thermionic emission temperatures. Electrons from the filament 250 bombard the cathode 224 to thereby also heat the cathode 224 to thermionic emission temperatures. Electrons emitted by the cathode may be accelerated and ionize gas molecules from the gas source 260 to produce a plasma discharge. The repeller 222 builds up a negative charge to repel electrons back through the arc chamber 204 producing additional ionizing collisions. Although electrons are provided by the cathode 224 in the embodiment of FIG. 2, those skilled in the art will recognize that other types of ion sources, e.g., a Bernas source, etc., would have different electron sources.

Regardless of the electron source, the plasma formed in the arc chamber 204 then sputter etches material from the sputter target 212, which in turn is ionized by electrons in the plasma. Ions are then extracted through the extraction aperture 215 into a well defined ion beam 105. The sputter target 212, and in particular the exposed face of the sputter target facing the plasma in the arc chamber 204, therefore erodes with use as material is sputter etched there from.

The feed system 210 advantageously replenishes the sputter target 212 by feeding the same into the arc chamber 204. The feed system 210 may allow for manual mechanical feed control of the sputter target 212 or automated feed control via the controller 218. For automated control, the selected feed rate for driving the sputter target 212 into the arc chamber 204 is selected in response to the erosion rate of the sputter target 212.

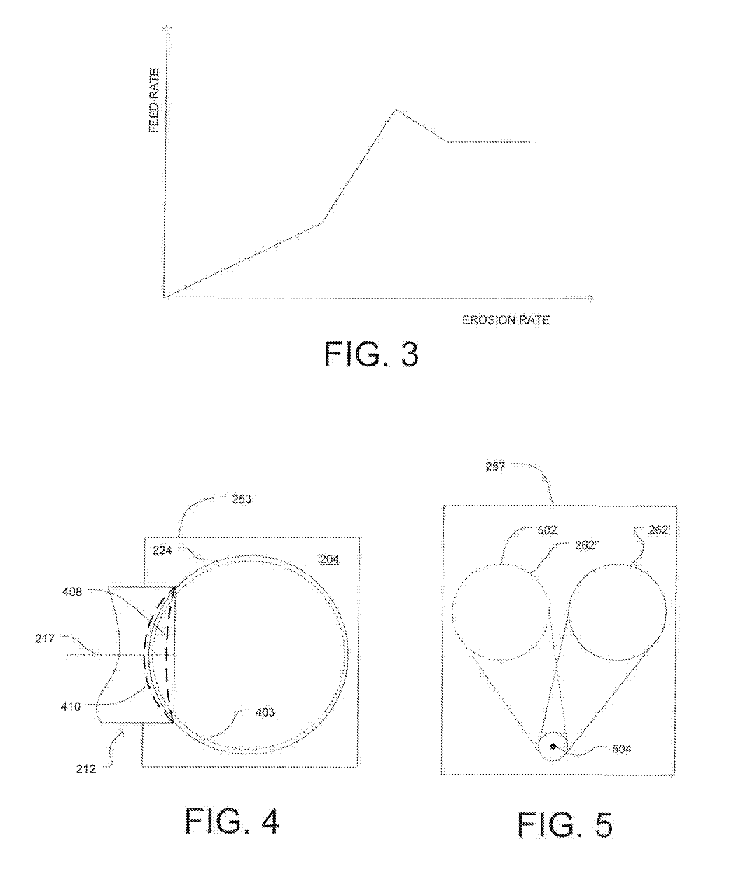

FIG. 3 illustrates a plot of the selected feed rate of the sputter target 212 into the arc chamber 204 versus the erosion rate of the exposed portion of the sputter target 212. In general, as the erosion rate increases so does the feed rate and vice versa. The erosion rate may be influenced by several parameters. One parameter is the type of solid material selected for the sputter target 212. Some materials tend to erode faster than others. Differing melting points and vaporization points also influence the erosion rate. Another parameter is the beam current of the ion beam 105. In general, a comparatively larger beam current would result in a faster erosion rate than a smaller beam current with all other parameters equal. Differing sensors such as Faraday cups known in the art can provide a feedback signal to the controller 218 representative of the actual beam current of the ion beam 105. Yet another parameter that may influence the erosion rate is the type of gas provided by the gas source 260 into the arc chamber 204. The controller 218 may analyze these and perhaps other parameters to select a desired feed rate for feeding the sputter target 212 into the arc chamber 204.

The feed system 210 may further be configured to fixedly couple the sputter target 212 to the shaft 216. In one embodiment, the shaft 216 may be a rotating shaft driven by the actuator 214. Accordingly, the shaft and sputter target 212 may rotate about the axis 217. The sputter target 212 may rotate while it is positioned in the arc chamber 204 and not being driven further into the same. In addition, the feed system 210 may further be configured to rotate the sputter target 212 as it is driven linearly into the arc chamber 204 in the direction of arrows 278. The rotation of the sputter target 212 about the axis 217 tends to help more evenly wear the surface of the sputter target exposed to the plasma.

Turning to FIG. 4, a cross sectional view along a longitudinal axis of the arc chamber 204 looking towards the cathode 224 is illustrated. The sputter target 212 is illustrated as approaching the arc chamber 204 from a similar vantage point as FIG. 2. The plasma 403 in the arc chamber 204 tends to have a cylindrical shape between the cathode 224 and repeller 222. The sputter target 212 tends to wear or is erode in a pattern approximating the shape of the plasma 403. Therefore, if the sputter target 212 was not rotated and the plasma 403 had such a cylindrical shape between the cathode 224 and repeller 222, the sputter target 212 may exhibit the wear pattern 410. Advantageously, if the sputter target 212 is rotated about the axis 217, the sputter target 212 would wear more evenly and could exhibit the wear pattern 408. Eroding the exposed portion of the sputter target 212 in a relatively uniform fashion may improve stability of the ion source and increase beam current levels of the ion beam extracted there from.

The ion source 102 may also be operated in a non-sputtering mode or an indirectly heated cathode mode for the embodiment of FIG. 2. In this indirectly heated cathode mode, the feed system 210 may completely withdraw the sputter target 212 from the arc chamber 204 and position the cover 262 in a closed position to block as associated aperture in the rear wall 257. The ion source 102 may then be operated as a conventional indirectly heated cathode (IHC) source by supplying a dopant gas from the gas source 260 and ionizing the same with electrons emitted from the cathode 224. Accordingly, the ion source 102 may be a multi-mode type ion source capable of being operated in both a sputtering mode and non-sputtering mode.

FIG. 5 is a view of one embodiment of the rear wall 257 of the ion source 102 with the cover 262 movable between an open 262′ and closed 262″ position. In the open position 262′, the cover 262 is pivoted about the pivot point 504 to to expose an aperture 502 in the rear wall 257 of the ion source 102. The feed system 210 may then drive the sputter target 212 into the arc chamber 204 through the aperture 502. The aperture may have different shapes depending on the cross sectional shape of the sputter target 212. In the embodiment of FIG. 5, the aperture 502 has a circular shape to accept a cylindrical shaped sputter target 212. These is shapes also facilitate rotation of the sputter target 212.

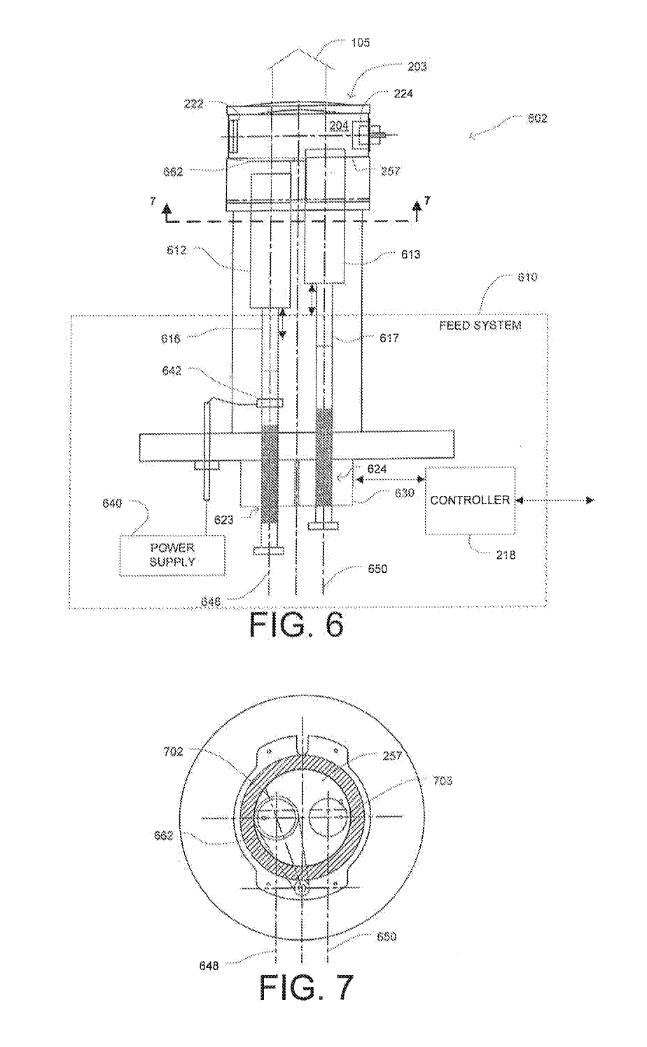

Turning to FIG. 6, a cross sectional plan view of another embodiment of an ion source 602 is illustrated. FIG. 7 is an end view of the rear wall 257 of the arc chamber housing 203 taken along the line 7-7 of FIG. 6. Like parts have like reference numerals and hence any repetitive description is omitted herein for clarity. Compared to the embodiment of FIG. 2, the embodiment of FIGS. 6 and 7 includes two sputter targets or a first sputter target 612 and a second sputter target 613. In the illustrated position of FIG. 6, the first sputter target 612 is removed from the arc chamber 204 and a cover 662 is in a closed position to cover an aperture 702 as is more clearly illustrated in FIG. 7. The second sputter target 613 has a portion positioned in the arc chamber 204 for sputtering of the same.

The feed system 610 includes a first rotating shaft 616 coupled to the first sputter target 612 and a second rotating shaft 617 coupled to the second sputter target 613. The shafts 616, 617 may include threads 623, 624 that engage a drive mechanism 630. The drive mechanism 630 may be a rotating drive to drive the shafts and hence the sputter targets 612, 613 linearly into and out of the arc chamber 204 while rotating the same about a first axis 648 and a second axis 650 respectively.

A power supply 640 may be electrically coupled to the first sputter target 612 via a rotating contact 642 coupled to the rotating shaft 616 and a conductive shaft material. The rotating contact 642 may be fabricated of differing conductive material. The power supply 640 may provide a bias signal to the first sputter target 612 to increase the sputtering rate of material by increasing the amount and intensity of particles attracted to first sputter target 612 which in turn can increase the beam current of the ion beam 105. Although not illustrated in FIG. 6, a similar bias scheme may be applied to the second sputter target 613.

In operation, the ion source 602 may be operated in one of several modes. In a first sputtering mode, the first cover 662 may be in an open position and the feed system 610 is configured to feed the first sputter target 612 through the first aperture 702 in the rear wall 257. A second cover (not illustrated) may be in a closed position to cover a second aperture 703 as the second sputter target 613 is positioned completely outside the arc chamber 204. In a second sputtering mode, the sputter targets may be reversed such that the second sputter target 613 is fed into the arc chamber 204, while the first sputter target 612 is completely removed and the first cover 662 is in a closed position as illustrated in FIG. 6. In yet another operating mode, both the first and second sputter targets 612, 613 may be fabricated of the same solid material and both may be fed into the arc chamber 204 at the same time. In yet another operational mode, both the first and second sputter targets 612, 613 may be completely removed from the arc chamber, the respective covers closed, and the ion source may operate in an indirectly heated cathode mode.

Accordingly, there is provided a feed system to feed a sputter target into an arc chamber. In one embodiment, the arc chamber may be an arc chamber of an ion source for a beam line ion implanter. The feed system allows for increased operational lifetime compared to a sputter target placed completely in the arc chamber with no feed system as the eroded sputter target may be continually refreshed. By using the feed system, a refreshed area and profile for sputtering may also be presented to the plasma in the arc chamber and hence profile control of the refreshed area may be provided. In addition, for an ion source of a beam line ion implanter, sputtering of the sputter target may also provide for an increased level of multiply charged species and dimer states compared to feeding a gas into the arc chamber. For instance, a desired B species obtained from sputtering a sputter target containing boron generally results in more doubly charged (B⁺⁺) and triply charged (B⁺⁺⁺) states than a conventional ion source feeding a dopant gas such as boron trifluoride (BF₃) into the arc chamber. The feed system also permits flexibility by enabling different operational modes as one or more sputter targets may be inserted into and removed from the arc chamber. In addition, for an ion source of a beam line ion implanter, many different types of ion beams with differing species, beam currents, etc. may be provided by the same ion source.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. An apparatus comprising:
an arc chamber housing defining an arc chamber; and
a feed system configured to feed a sputter target into the arc chamber.

2. The apparatus of claim 1, wherein the feed system is configured to feed the sputter target into the arc chamber at a selected feed rate in response to an erosion rate of the sputter target.

3. The apparatus of claim 1, wherein the feed system is configured to feed a portion of the sputter target into the arc chamber while a remaining portion of the sputter target is positioned outside of the arc chamber.

4. The apparatus of claim 1, wherein the feed system comprises a shaft coupled to the sputter target, and wherein the shaft is configured to drive a portion of the sputter target into the arc chamber at a selected feed rate in response to an erosion rate of the portion.

5. The apparatus of claim 4, wherein the shaft comprises a rotating shaft fixedly coupled to the sputter target, and wherein the feed system is further configured to rotate the sputter target as it is driven into the arc chamber.

6. The apparatus of claim 5, wherein the feed system further comprising a rotating contact coupled to the rotating shaft, wherein the rotating contact provides an electrical contact for a bias signal to bias the sputter target.

7. The apparatus of claim 1, wherein the arc chamber housing comprises a first aperture and a first cover, wherein the first cover is in an open position when the ion source is operating in a first sputtering mode, and wherein the feed system is configured to feed the sputter target through the first aperture into the arc chamber.

8. The apparatus of claim 7, wherein the arc chamber housing further comprises a second aperture and a second cover, wherein the second cover is in an open position and the first cover in a closed position when the ion source is operating in a second sputtering mode, and wherein the feed system is configured to feed a second sputter target through the second aperture into the arc chamber.

9. The apparatus of claim 7, wherein the sputter target has a cylindrical shape and the first aperture has a circular shape to accept the cylindrical shape.

10. The apparatus of claim 7, further comprises a cathode positioned at one end of the arc chamber and a repeller positioned at an opposing end of the arc chamber, wherein the feed system is configured to remove the sputter target from the arc chamber, and wherein the first cover is in a closed position when the apparatus is operating in an indirectly heated cathode mode.

11. A method comprising:
feeding a sputter target into an arc chamber defined by an arc chamber housing; and
etching particles from the sputter target.

12. The method of claim 11, further comprising ionizing the particles from the sputter target.

13. The method of claim 12, further comprising positioning one portion of the sputter target inside the arc chamber and a remaining portion of the sputter target outside of the arc chamber when ionizing the particles from the sputter target.

14. The method of claim 13, further comprising extracting an ion beam from an extraction aperture defined by the arc chamber housing.

15. The method of claim 11, further comprises feeding the sputter target into, the arc chamber at a selected feed rate in response to an erosion rate of the sputter target.

16. The method of claim 11, further comprising rotating the sputter target while feeding the sputter target into the arc chamber.

17. The method of claim 16, further comprising biasing the sputter target.
